(19) United States
(12) Patent Application Publication
(10) Pub. No.: US 2008/0001679 A1
(43) Pub. Date: Jan. 3, 2008

(54) Crystal Oscillators

(76) Inventors: Cameron J. Kerpert, Sydney (AU); Karena W. Chapman, Sydney (AU)

Correspondence Address: JONES DAY, 222 EAST 41ST ST, NEW YORK, NY, 10017, US

(21) Appl. No.: 10/586,333

(22) PCT Filed: Jan. 13, 2005
(86) PCT No.: PCT/AU05/00033

§ 371 Date: Aug. 1, 2007

(30) Foreign Application Priority Data
Jan. 15, 2004 (AU) 2004900172

(51) Int. Cl. H03H 9/17; H03H 3/04; H03H 9/02

(52) U.S. Cl. 331/158; 29/25.35

(57) ABSTRACT

A crystal-controlled oscillator comprises a crystal that is formed from a material that is suitable for use in the oscillator. However, the thermal expansion characteristic of the material itself enables temperature dependence of the oscillator frequency to be controlled over an operating temperature range for the oscillator. A timing device may incorporate the crystal-controlled oscillator.

### TECHNICAL FIELD

A new type of crystal oscillator is disclosed that has broad application in replacing existing crystal oscillators in all technical fields in which such oscillators are employed, including as timing devices.

### BACKGROUND ART

A vast majority of materials expand when heated. This behaviour is often undesirable in many technological fields. This is equally the case with known crystal oscillators.

An oscillator is a circuit that generates an RF output signal through feedback and amplification. Usual wave forms output by an oscillator include sinusoidal, square, triangular and saw-toothed. Crystal oscillators are oscillators where the primary frequency determining element, known as a regulator, is a piezoelectric crystal. The crystal replaces an L-C tuned circuit to significantly improve the oscillator's frequency stability. This is because it is almost impossible to produce a stable and accurate L-C oscillator for upper HF and higher frequencies without crystal control.

Quartz is the standard regulator employed almost exclusively in crystal oscillators. Quartz is a known piezoelectric material and accordingly displays a reciprocal relationship between mechanical deformation along one crystal axis and the appearance of an electrical potential, usually along another axis. When a voltage with a variable frequency is applied to the crystal, the crystal is caused to mechanically oscillate at one of a number of resonant frequencies. The resonant frequencies of a given crystal are determined by its geometry, that is, its thickness and directionality. Quartz is the standard material employed in crystal oscillators because it can be held to extreme accuracy of frequency stability. However, as with other materials, quartz is affected by temperature variations, altering the crystal dimensions and hence resonant frequency.

Accordingly, where high accuracy frequency stability is required in the oscillator, various types of temperature compensation arrangements must be employed with quartz crystals. These include:
microcomputer-compensated crystal oscillators (MCXO) used in spread spectrum system clocks, MTI radars, wireless base stations, telecom timing modules and precision test equipment;
oven controlled voltage controlled crystal oscillators (OCVCXO) used in navigation system clocks, frequency standards, MTI radars, wireless base stations, telecom timing modules, precision test equipment and in phase lock loop circuits in telecom timing, wireless base stations and fibre optic timing;
oven controlled crystal oscillators (OCXO) where the crystal is kept at a constant temperature inside an enclosing oven, and including double oven controlled crystal oscillators (DOCXO) where a double oven is used to maintain tighter temperature control, the OCXOs and DOCXOs being used in wireless base stations, telecom timing modules and precision test equipment;
temperature compensated voltage controlled crystal oscillators (TCVCXO) used for frequency control in tactical radios, telecom timing modules, wireless systems and reference oscillators;
temperature compensated crystal oscillators (TCXO) that employ a temperature compensation circuit to achieve a stabilised quartz frequency, and used in telecom timing modules and wireless systems reference oscillators (such as microwaves etc); and
voltage controlled temperature compensated crystal oscillators (VCTCXO) having electronic frequency modulation input to control the output frequency and having a temperature compensation circuit, and used in phase lock loop circuits in telecom timing modules and wireless systems reference oscillators.

Simple crystal oscillators, generally referred to as crystal oscillators (XO) and crystals (X), are used as a frequency timing reference in microprocessor circuits, telecom timing circuits, ethernet transceivers etc. These are uncompensated and hence are less accurate and more susceptible to temperature effects.

The above referenced devices find use in military & aerospace, research & measurement, industrial, automotive and consumer applications. In a number of these applications, thermal stability of the crystal oscillator is critical, as accuracy is critical. Hence, oscillators will be employed that have one or more of microprocessor compensation, temperature-compensation, oven control etc to stabilise device operation over broader temperature ranges. As a result, additional complexities and cost are introduced in the manufacture and operation/performance of the oscillators.

In addition, significant precision and control must be exercised in the manufacture and preparation of the quartz crystal for the oscillator. For this reason, cultured rather than natural quartz is exclusively employed, as the shape and defect concentration of the raw/blank crystal can be made uniform. Further, the growth of cultured quartz requires high temperatures and large time scales.

Once the quartz has been grown, accurate cutting saws must be employed to cut the crystal. The angle of cut has a direct relationship to the frequency versus temperature characteristic and hence x-ray equipment is employed to ensure precise orientation of the cutting saws. Then, the crystal thickness and frequency is finely adjusted by lapping the quartz whereby a quartz wafer is produced by grinding away wafer surfaces using abrasives. Quartz flatness and thickness must be maintained and accuracies of considerably less than 0.1 millimetre are required. In addition, the thinner the quartz crystal the higher the frequency, with very thin crystals requiring very careful and expensive lapping. After this, the crystal must be dimensioned to tight tolerances, then etched in an acidic solution to improve surface finish and to reduce frequency spread, with all these stages requiring an extremely clean environment.

To form the crystal into a piezoelectric device, high vacuum film deposition deposits a metal onto the surface of the crystal blank to form the desired electrode pattern prior to the crystal being mounted into its oscillator and then plated and finally sealed. Prior to sealing, any compensation circuits must first be incorporated and, during sealing, oven configurations for temperature control are fabricated into the oscillator. Most of these temperature control stages add significantly to the complexity and cost of the oscillator.

When the present applicant developed materials, such as those set forth in its co-pending application PCT/AU03/00864, it was not aware that some such materials had then unforeseen properties that might enable the materials to be employed in a crystal oscillator.

### SUMMARY OF THE DISCLOSURE

In a first aspect there is provided a crystal-controlled oscillator, the crystal being formed from a material that is suitable for use in the oscillator, characterised in that the thermal expansion characteristic of the material itself enables temperature dependence of the oscillator frequency to be controlled over an operating temperature range for the oscillator.

In a second aspect there is provided a timing device incorporating the crystal-controlled oscillator of the first aspect.

The applicant has discovered and developed certain materials suitable for use as a crystal in an oscillator that have an intrinsic expansion characteristic that allows for intrinsic control of the temperature dependence of oscillator frequency (ie. without the need for any compensation external to the material or oscillator).

For example, crystals can be formed that, over an operating temperature range for the oscillator, have a thermal expansion characteristic that is zero or near zero, or that display expansion that has a negligible effect on the temperature dependence of oscillator frequency. Thus, the dependence of oscillator frequency on temperature can be substantially eliminated or be negligible, so that the elaborate temperature compensation configurations of the prior art can be avoided.

Notably, the thermal expansion characteristics of known oscillator materials (such as quartz) are not themselves adapted to enable the temperature dependence of oscillator frequency to be controlled over an operating temperature range for the oscillator. Rather, the known materials are directly susceptible to temperature change.

Whilst the achievement of near zero oscillator frequency dependence with temperature is a desirable outcome, it should be appreciated that the suitable materials herein are not limited or confined to a near zero oscillator frequency dependence. For example, a simple frequency dependence can be useful in some applications; eg. a linear change in frequency with temperature can be very easily corrected for in a simple TCXO incorporating a suitable crystal material herein. By way of contrast, quartz has complicated temperature dependence, making correction for this in TCXOs difficult, complex and costly.

In addition, some suitable crystal materials having zero thermal expansion may not necessarily have zero frequency dependence, since the oscillator frequency may also be affected by the Young's Modulus of that material. In some suitable materials herein, the Young's Modulus may be temperature dependent and then a combination of thermal expansion and Young's Modulus can determine the frequency dependence of the material when used as an oscillator. Again, however, this can be easily accommodated and/or compensated for in many suitable applications of the material.

In other suitable materials herein a zero thermal expansion material is likely to give zero or very near zero frequency dependence, with such non-zero frequency dependence being due to a very minor influence of temperature dependent Young's Modulus, and again can be easily accommodated and/or compensated for as necessary.

In any case, the applicant has observed that the temperature dependence of the Young's Modulus will generally be a minor influence compared to thermal expansion, and has noted that the critical aspect to crystal performance in an oscillator is control over the thermal expansion.

Hence, in this specification, the expression “enables temperature dependence of the oscillator frequency to be controlled” is to be interpreted broadly and not necessarily as implying zero frequency dependence or an approach to zero.

When the terminology “zero thermal expansion” (or “ZTE”) is employed herein it is to noted that this encompasses zero material expansion that is anisotropic (along one direction) and zero material expansion that is isotropic (in all directions). Again, in certain applications of crystal-controlled oscillators, a crystal that displays at least anisotropic zero thermal expansion behaviour can be sufficient for that application and can still represent a significant improvement over known crystals such as quartz.

The thermal expansion characteristics of certain suitable materials may be “tuned” and hence the terminology “tunable thermal expansion” or “TTE” will be employed herein. In this regard, TTE crystal materials that are suitable in an oscillator may have been tuned to provide zero frequency dependence “ZFD” or to provide simple/linear frequency dependence “SFD/LFD”. Furthermore, certain TTE crystal materials that are suitable in an oscillator may have been tuned to accommodate or compensate for the influence of a temperature dependent Young's Modulus of those materials.

Thus, timing devices can be more easily produced using the suitable materials herein. The materials used in the timing devices may comprise TTE or ZTE crystals having a piezoelectric property that make them suitable for use in an oscillator of the timing device. The resulting timing devices can then be employed in a wide range of applications, such as those outlined in the Background, without the need for either complex or any temperature compensation arrangements (such as microprocessor compensation, oven control etc). This can considerably simplify the construction of the timing device and reduce its cost to manufacture.

The terminology “timing device” is also to be interpreted broadly and should not be construed as limited to a clock per se. Rather, the terminology is to be construed to include any device having any of the applications of crystal-controlled oscillators as outlined above. In addition, it should be noted that the term “crystal-controlled oscillator” is often abbreviated to “crystal oscillator” and hence the applications of suitable materials to a timing device include their use in a crystal oscillator.

In one mode the thermal expansion characteristic of the material is adapted by tuning the coefficient of thermal expansion of the material. The coefficient of thermal expansion α1, is defined as the relative change in length per unit temperature change.

Tuning can be achieved by:
(1) modifying the composition of the crystal (eg. by doping etc, as outlined in the specific description); and/or
(2) recognising that a material has ZTE (or a characteristic closely approaching ZTE) along at least one direction, and then selecting this direction when a crystal of the material is cut.

Known oscillator materials such as quartz do not have ZTE or any characteristic even closely approaching ZTE. Furthermore, as piezoelectric materials are anisotropic, thermal expansion will be different along different directions of the crystal.

Thus, in one embodiment, to achieve (1) and/or (2) with the suitable materials disclosed herein the following steps can be followed:
(i) identify a material having a suitable thermal expansion characteristic and that is also piezoelectric. In (i) it is to be noted that piezoelectric crystals are “non-centrosymmetric” and “non-cubic”, although the extent of the piezoelectric effect can vary greatly even where these structural characteristics are present.
(ii) cut the crystal, optimally so that it is ZTE in the direction of the cut, as this should give near ZFD (zero frequency dependence).
(iii) determine the temperature dependence of the oscillator frequency for this cut crystal.
(iv) if necessary, modify the direction of the cut to give less temperature dependence, whilst recognising both the CTE (coefficient of thermal expansion) and Young's Modulus.
(v) as necessary, modify the chemical composition of the crystal by doping in other elements.

A typical operating temperature range for an oscillator is from −55° C. to +125° C. and suitable materials herein can maintain ZTE in this range. Further, suitable materials herein can enable the range in which a controlled thermal expansion (zero or simple/linear) is maintained to be extended from −200° C. to +150° C. In addition, suitable materials herein are physically stable up to 500° C., making them stable within typical manufacturing temperature ranges for crystal-controlled oscillators.

Suitable materials herein can be grown as single crystals to typical size ranges for crystal-controlled oscillators (eg. from 1 mm up to and beyond 5 mm in diameter, length and/or width). Crystal growth may occur by slow diffusion at ambient temperature or by solvothermal synthesis at higher temperatures. Both of these techniques are substantially simpler and cheaper than known techniques used to grow quartz crystals.

Suitable materials herein may have a piezoelectric effect at least comparable to quartz and in some cases greater. Where the effect is less than quartz, the only drawback noted is that the oscillator can draw more power.

Suitable crystalline materials herein comprise a plurality of diatomic bridges, the or each bridge extending between two atoms in the material, with the or each diatomic bridge having at least one vibrational mode that causes the two atoms on either side of the bridge to be moved together to the same extent as competing vibrational mode(s) that cause the two atoms on either side of the bridge to be moved apart. Such a material displays zero thermal expansion (ZTE) behaviour.

Suitable crystalline materials herein include =Zn^{II}[Ag^{I}(CN)₂]₂.0.575{AgCN}, Zn^{II}[Au^{I}(CN)₂]₂, KCd^{II}[Ag^{I}(CN)₂]₃, KMn[Ag^{I}(CN)₂]₃ and KCd^{II}[Au^{I}(CN)₂],₃, which display both ZTE along at least one axis and a piezoelectric effect.

Alternatively, the crystalline material can have either a negative thermal expansion characteristic or a positive thermal expansion characteristic, but in either case modified (eg. doped) to have ZTE.

In a third aspect there is provided the use of a material in a crystal-controlled oscillator, characterised in that the thermal expansion characteristic of the material itself enables temperature dependence of the oscillator frequency to be controlled over an operating temperature range for the oscillator.

The crystal-controlled oscillator of the third aspect can be used in a timing device.

In a fourth aspect there is provided a method of fabricating a crystal for an oscillator from a piezoelectric material having a thermal expansion characteristic that enables temperature dependence of the oscillator frequency to be controlled over its operating temperature range, the method comprising the step of cutting the material in a manner that imparts to an oscillator formed therefrom a near zero, negligible or simple frequency dependence over its operating temperature range.

The crystal can also be formed to have a zero or near zero thermal expansion characteristic along at least one axis therethrough.

The crystal can be grown by slow diffusion at ambient temperature or by solvothermal synthesis at temperatures higher than ambient. During crystal growth, the thermal expansion properties of the crystal can be modified by selective doping of metal sites, modification of guest molecules, modification of counter-ions, and/or by altering the degree of interpenetration of material topology. After crystal growth, the thermal expansion properties of the crystal can be optimised by cutting the crystal along a direction in which the material has a ZTE characteristic, or a characteristic closely approaching ZTE.

### BRIEF DESCRIPTION OF THE DRAWINGS

Notwithstanding any other forms which may fall within the disclosure, specific embodiments will now be described, by way of example only, and with reference to the accompanying drawings in which:

FIG. 1 shows a representation of a suitable material herein, being the basic structural unit present in Zn^{II}[M^{I}(CN)₂]₂.x{guest} (where M=Ag; Au and {guest} is as defined below);

FIG. 2(a) shows a representation of a suitable material herein, being one of the six interpenetrating beta quartz-type networks present in the structure of Zn^{II}[M^{I}(CN)₂]₂ (where M=Ag; Au);

FIGS. 2(b) and 2(c) show representations of suitable materials herein, being six interpenetrating beta quartz-type networks present in the structures of Zn^{II}[Ag^{I}(CN)₂]₂.0.575{Ag^{I}

### CN} (which contains 1-dimensional chains of Ag^{I}CN within channels running through the networks) and Zn^{II}[Au^{I}(CN)₂]₂ (which contains empty channels);

FIGS. 3(a) and 3(b) show two graphs of the thermal expansion behaviour of two respective members of suitable materials herein, being the Zn^{II}[M^{I}(CN)₂]₂.x{guest} family (where M=Ag; Au and {guest} is as defined below);

FIG. 4 shows a representation of a suitable material herein, being the basic structural unit in the KCd^{II}[M^{I}(CN)₂]₃ family (where M=Ag; Au);

FIG. 5 shows a representation of a suitable material herein, being one of the distorted cubic nets present in the structure of the KCd^{II}[M^{I}(CN)₂]₃ family; and

FIGS. 6(a) and 6(b) show two graphs of the thermal expansion of suitable materials herein, being two respective members of the KCd^{II}[M^{I}(CN)₂]₃ family (where M=Ag; Au).

### DETAILED DESCRIPTION OF SPECIFIC EMBODIMENTS

The inventors first verified anomalous thermal expansion. The initial identification of anomalous expansion was negative thermal expansion (NTE) in Zn(CN)₂. The inventors noted the NTE in Zn(CN)₂ to be continuous, monotonic and nearly linear over a large temperature range. By analysis, the present inventors were able to attribute this to thermal motion of the CN bridges by correlating the extent of NTE to the behaviour of the thermal parameters of the CN bridge. The thermal motion of the CN bridges was then interpreted by the present inventors in terms of vibrational modes, and in turn, phonon modes. Two different types of transverse vibrational modes were discovered in M-CN-M′ containing components. The first (referred to hereafter as “δ₁”) involved the displacement of the entire CN bridge away from the M-M′ axis in such a way that both the C and N atoms moved in the same direction. The second (hereafter referred to as “δ₂”) involved, in effect, a rotation of the CN bridge about an axis perpendicular to the central M-M′ axis, causing the C and N atoms to move in opposite directions. The present inventors noted that these vibrational modes were consistent with the rigid unit theory of phonon modes. This analysis implied that the transverse vibrational modes of diatomic (and optionally polyatomic) bridges impacted significantly on the distance between two atoms A and B joined by that bridge.

Thus, suitable materials herein typically exhibit δ₁- and δ₂-like vibrational modes to attain zero thermal expansion behaviour, at least along one axis. Typically the population of the δ₁- and δ₂-like vibrational modes increases when the material is heated in a manner that maintains ZTE, although radiation (eg. infra-red radiation) or another energy source may also have the same effect.

As a further alternative, ZTE behaviour can be achieved in cyanide-containing materials through material modification (eg. Zn[Au(CN)₂]₂.x{guest}, where {guest} is as defined below), where the behaviour arises not only from the δ₁- and δ₂-like vibrational effects, but from lattice effects. In this regard, such materials can include a plurality of diatomic bridges throughout an infinite molecular coordination network defining a lattice structure, whereby changes in lattice geometry can influence thermal expansion behaviour. Thus, heating of these materials can cause the geometry of the lattice itself to change, resulting in uniaxial or anisotropic ZTE.

In addition to these effects, other influences can be used to achieve ZTE in a material displaying NTE along at least one axis, including how the crystal is cut (eg. along an axis displaying ZTE), phase transitions, magnetic and electronic transitions and other (not necessarily CN-based) rigid unit modes (RUMs) or phonon modes.

The inventors also noted that suitable ZTE materials may comprise linear diatomic bridges, such as a linear cyanide —(CN)— bridge. However, non-linear cyanide or other diatomic bridges may still provide ZTE materials, at least along one axis of a crystal of the material. As a further alternative, suitable materials herein may comprise diatomic bridges such as a carbon monoxide —(CO)— bridge, a di-nitrogen —(NN)— bridge, a nitrogen monoxide —(NO)— bridge, and possibly even a carbide —(CC)— bridge etc.

The atoms that the diatomic bridge extends between can be metals or semi-metals but may also be non-metals and combinations thereof. The two atoms on either side of the bridge can be different atoms, being different metals, semi-metals and non-metals, and combinations thereof.

As another alternative, the inventors noted that zero thermal expansion of the material can be maintained by varying the relative ratios between two or more different atoms on either side of the diatomic bridge. In this regard, during material formation, different atoms (eg. a different metal ion) can be “doped” into the material to tune (eg. fine-tune) expansion behaviour to ZTE.

When a cyanide ion is coordinated to a metal or semi-metal atom, the inventors noted that the metal atom may coordinate one or more other cyanide ions, which in turn can bridge to other atoms. However, to achieve ZTE in suitable crystal materials, each atom may also coordinate other ligands. These ligands may be uni- or multi-dentate, including but not limited to water, alcohols, diols, thiols, oxalate, nitrate, nitrite, sulfate, phosphate, oxide, sulfide, thiocyanate, non-bridging cyanide, cyanate, nitrogen monoxide, carbon monoxide, dinitrogen etc. Thus, the material can comprise a salt crystal. This salt may also be desolvated (usually by heating the salt to drive off the solvent). In this regard, in desolvated salts, it is also not necessary for all coordination sites of the metal atom to be satisfied by a coordinating ligand.

Where the atoms coordinate with other ligands, the inventors noted that the suitable materials herein may form part of an assembly that is neutrally, positively or negatively charged. The assembly can, for example, comprise a rigid connected part of the material. When the assembly carries a charge, counter-ions may be incorporated within cavities or pores within the assembly to provide neutrally charged materials. These counter-ions may themselves influence the thermal behaviour of the material, and may also act to influence the expansion behaviour of the material as a whole (ie. by counteracting negative thermal expansion to achieve zero thermal expansion).

The inclusion of counter-ions into the assembly or pores thereof can also allow for tuned expansion of the material to ZTE eg. where the ability to tune the expansion properties arises from ion exchange. In this regard, such tuned expansion can be performed in-situ or by varying preparative conditions. The counter-ions can be varied either by ion exchange or synthetic modification, to vary the thermal expansion behaviour of the material.

The inventors also noted that the assembly may include guest molecules (herein sometimes referred to as “{guest}”) in interstitial cavities within a lattice thereof. A number of different types of guest molecules may be incorporated into the assembly. The guest molecules may also confer on the material the ability to exhibit expansion tuned to ZTE, where the ability to tune the expansion properties in this case arises from solvent exchange and/or solvent sorption and desorption. Again, such tuned expansion can be performed in-situ or by varying preparative conditions. In this regard the guest molecules can counteract negative thermal expansion behaviour of the material to achieve ZTE. When the crystal material is porous the guest molecules can be located in pores of the material. The guest molecules can be varied either by sorption/desorption or synthetic modification, to vary the thermal behaviour of the material. The guest molecules can comprise one of more of water, alcohols, organic solvents or gas molecules.

The inventors have observed that the number of possible topologies of such materials is essentially limitless. The topology of a particular material can be determined to some extent by the number of diatomic bridges (eg. cyanide ions) coordinated to each metal centre, and the geometry of this coordination. For example, the topology may be based on a diamond-, wurzite-, quartz-, cubic-, (4,4)-, (6,3)-, (10,3)-, PtS—, NbO—, Ge₃N₄—, ThSiO₂— or PtOₓ-type net. The material may comprise more than one interpenetrating net, and these nets may or may not be of the same topology.

The number, topology and size of interpenetrating nets may also affect the solvent or ion accessible volume of the material. Suitable crystal materials may also comprise zero-dimensional bridged moieties, such as CN bridged molecular squares.

Further, the suitable crystal materials may comprise one or more multi-atomic bridges, the or each bridge extending between two atoms in the material. Again, the or each multi-atomic bridge can have at least one vibrational mode that causes the two atoms on either side of the bridge to be moved together to the same extent than competing vibrational mode(s) that cause the two atoms on either side of the bridge to be moved apart, to thereby achieve ZTE.

Both di- and poly-atomic bridges can be employed, for example, the di-atomic bridges as defined above, and polyatomic bridges such as cyanamide, dicyanamide, tricyanomethanide, thiocyanate, selenocyanate, cyanate, isothiocyanate, isoselenocyanate, isocyanate, azide, cyanogen and butadyinide.

The two atoms on either side of the bridge can be different atoms such that the thermal expansion is tunable to ZTE by varying the relative ratios between the two or more different atoms on either side of the diatomic bridge. The two atoms on either side of the bridge can be different metals, semi-metals or non-metals, or combinations thereof.

The present inventors discovered that, depending on the proportion, distribution and type of diatomic bridges in a given crystal material, zero thermal expansion (ZTE) can be achieved. In addition, by controlling the proportion, distribution, type of diatomic bridge and the atoms being bridged, the inventors was able to obtain ZTE.

Advantageously all of these materials can have controlled thermal expansion behaviour. Because the suitable materials also display a piezoelectric effect, an oscillator employing such materials is also more reliable and stable in use over broad temperature ranges and during temperature fluctuations.

Thus, having achieved material ZTE behaviour over typical operating temperature ranges for an oscillator, in various materials and by various material modifications, the present inventors thus determined whether a given ZTE material displayed a piezoelectric effect. In this regard, the inventors identified whether or not the material was non-centrosymmetric and non-cubic (a characteristic of piezoelectric materials). Only a certain number of crystalline materials that displayed ZTE also displayed a piezoelectric effect, and these are described below in Examples 1 to 4.

### Specific Material Embodiments.

ZTE behaviour was investigated with a range of solid crystal materials potentially suitable for a crystal oscillator for eg. a timing device. As outlined below, suitable materials had significant advantages over prior art crystals (especially the standard quartz). Initial materials investigated were certain cyanide-bridged materials.

For example, Cd(CN)₂ exhibits isotropic NTE with a coefficient of thermal expansion (CTE) of −21×10⁻⁶ K⁻¹ but does not display a piezoelectric effect. Zn[Au(CN)₂]₂ was observed to exhibit anisotropic NTE, with a CTE in one direction of −62×10⁻¹ K⁻¹, and advantageously was observed to exhibit ZTE in other directions. In addition, Zn[Au(CN)₂]₂ was also observed to exhibit a piezoelectric effect as thus was deemed a suitable material.

The inventors thus noted that an anisotropic material can have different CTEs along different directions. For example, Zn[Au(CN)₂]₂ has positive thermal expansion along two directions and NTE along the third direction. However, there are a set of directions within the crystal which are ZTE, with a full range of intermediate CTEs along other directions. Thus, depending on how the crystal is cut, ZTE in an oscillator employing the crystal can be enhanced.

The inventors noted the following advantages:
The synthesis of crystal materials including a cyanide-bridged component was considerably simpler than prior art materials such as quartz.
Suitable materials were able to be synthesised using conventional solvents (such as water), at room temperature, and without specialist equipment, and the starting materials were often low cost and readily available;
The thermal expansion properties of non-ZTE materials were able to be tuned to ZTE by selective doping of metal sites, modification of guest molecules, modification of counter-ions, and degree of interpenetration of material topology;
The materials were able to be grown as large single crystals.

These far-reaching improvements rendered the suitable materials herein of significant application in a wide range of timing devices and in other applications of crystal oscillators, such as in microphones and sensors (converting a mechanical force into an electronic signal) and in speakers, etc. (converting an electronic signal into a mechanical force).

Various materials developed by the inventors including cyanide diatomic bridges will now be described, including their synthesis and characterisation. The following materials were constituted by “infinite” molecular coordination networks (for example, where the diatomic bridge is present throughout the material) to thus enable single crystal structures to be formed.

### Specific Material Examples:

The following examples (a) to (f) are materials that can be made ZTE (or include ZTE along one direction) but do not exhibit a piezoelectric effect, as their structure is centrosymmetric and/or cubic. However, they are disclosed herein because slight material modification of any of these examples (using the various means as outlined above) can convert them into non-centrosymmetric and non-cubic, thereby rendering them with a piezoelectric effect.

(a) Materials based on the Zn(CN)₂-type or 2×(6,4) cubic structure (doubly interpenetrating diamond-type nets). Variations included substitution of divalent metals for some or all of the Zn atoms. Such divalent metal ions included Cd(II), Hg(II), Mn(II), Be(II), Mg(II), Pb(II) and Co(II). Variations also included substitution of mixtures of univalent, divalent and trivalent metal ions for Zn to give materials of the form: {(M1₁^{II})ₓ₁(M1₂^{II})_{x2 . . .} (M1ₙ^{II})ₓₙ}{(M2₁^{I})(M₃₁^{III})}_{y1}{(M2₂^{I})(M3₂^{III})}_{y2 . . .} {(M2ₘ^{I}) (M3ₘ^{III})}_{ym}(CN)₂ where M1₁ included Zn(II), Cd(II), Hg(II), Mn(II), Be(II), Mg(II), Pb(II) and Co(II); M2ⱼ included Li(I) and Cu(I); M3ₖ included Al(III), Ga(III) and In(III); n and m being any non-negative whole numbers with at least one greater than or equal to unity; and (x1+x2+ . . . +xn)+2×(y1+y2+ . . . +ym)=1. Examples of this class included Zn(CN)₂, Zn_{0.8}Cd_{0.2}(CN)₂, Zn_{0.64}Cd_{0.36}(CN)₂, Cd(CN)₂, Mn(CN)₂, Zn_{0.5}Hg_{0.5}(CN)₂, Li_{0.5}Ga_{0.5}(CN)₂ and Cu_{0.5}Al_{0.5}(CN)₂.

(b) Materials of the general formula given in (a) above but with a single diamond-type network rather than two interpenetrating networks, optionally with counterions or molecules incorporated into the structure. Incorporation of counterions into the interstitial cavities required an appropriate inclusion of lower- or higher-valent metals into the network lattice. Examples of this class included Cd(CN)₂.½CCl₄, [NMe₄]_{0.5}[Cu^{I}_{0.5}Zn^{II}_{0.5}(CN)₂], Cd(CN)₂.CMe₄, Cd(CN)₂.CMe₃Cl, Cd(CN)₂.CMe₂Cl₂, Cd(CN)₂.CMeCl₃, Cd(CN)₂.CCl₄, Cd_{0.5}Hg_{0.5}(CN)₂.CCl₄, Cd_{0.5}Zn_{0.5}(CN)₂.CCl₄.

(c) Materials of the general formula given in (a) and (b) above but with more than two interpenetrating diamond-type networks.

(d) Materials based on the Ga(CN)₃-type cubic structure. Some such materials satisfied the general formula {(M1₁^{III})ₓ₁(M1₂^{III})_{x2 . . .} (M1ₙ^{III})ₓₙ}{(M2₁^{II})(M3₁^{IV})}_{y1}{(M2₂^{II})(M3₂^{IV})}_{y2 . . .} {(M2ₘ^{II})(M3ₘ^{IV})}_{ym}(CN)₃ where M1 included trivalent metal ions such as Fe(III), Co(III), Cr(III), Ti(III), Al(III), Ir(III), Ga(III), In(III) and Sc(III); M2 included divalent metal ions such as Mg(II), Zn(II), Cd(II), Co(II), Fe(II), Ru(II), Mn(II) and Ni(II); M3 included tetravalent metal ions such as Pd(IV) and Pt(IV); n and m being non-negative whole numbers with at least one greater than or equal to unity; and (x1+x2+ . . . +xn)+2×(y1+y2+ . . . +ym)=1. Examples of this class included Ga^{III}(CN)₃, Co^{III}(CN)₃, Al^{III}(CN)₃, Cd^{II}_{0.5}Pt^{IV}_{0.5}(CN), and Zn^{II}_{0.5}Pt^{IV}_{0.5}(CN)₃.

(e) Materials of the general formula given in (d) above but with other ions or molecules being incorporated into the structure. Incorporation of ions into the interstitial cavities required an appropriate inclusion of lower- or higher-valent metals into the network lattice. Examples of this class included the known Prussian blues compounds (e.g., K[Fe^{II}Fe^{III}(CN)₆]) and their analogues (e.g., Cs₂[Li^{I}Fe^{III}(CN)₆], Cd^{II}_{0.5}Pt^{IV}_{0.5}(CN)₃.H₂O, Zn^{II}_{0.5}Pt^{IV}_{0.5}(CN)₃.H₂O, K[Fe^{II}Fe^{III}(CN)₆].xH₂O).

(f) Materials of the types described in (d) to (e) above but with more than one interpenetrating cubic framework.

(g) Other simple metal cyanides not explicitly belonging to classes (a) to (f) above of the general form (M1ⁿ¹⁺)ₓ₁(M2ⁿ²⁺)_{x2 . . .} (Mk^{nk+})ₓₖ(CN)ᵢ(.{guest}) where M1, M2 . . . Mk were metals with oxidation states n1+, n2+ . . . nk+ respectively; k and i were positive whole numbers; (x1×n1)+(x2×n2)+ . . . +(xk×nk)=i; and {guest}, when present, included any solvent or molecular species such as water, alcohols, organic solvents or gas molecules. Such materials optionally comprised single or multiple interpenetrating regular nets, such as the quartz, NbO, PtS, Ge₃N₄, (10,3), ThSiO₂, PtOₓ or wurtzite nets. Examples included Ag^{I}CN, Au^{I}CN, Zn^{II}Ag^{I}₂(CN), and Zn^{II}Au^{I}₂(CN)₄.

(h) Materials of the general formula given in (g) above but with other ions or molecules incorporated into the structure. Incorporation of ions into the interstitial cavities required an appropriate inclusion of lower- or higher-valent metals into the network lattice. Examples included KCd^{II}[Ag^{I}(CN)₂], and KCd^{II}[Au^{I}(CN)₂].

(i) Materials of the general formula given in (g) above but which contain more than one type of network lattice. Examples included Zn^{II}Ag^{I}₂(CN)₄.0.575Ag^{I}CN.

(j) Materials of the types described in (a) to (i) above but with metal and/or cyanide vacancies within the structure. Such materials were optionally related to materials belonging to classes (a) to (h) by inclusion of metal and/or cyanide vacancies. Examples of this class included Mn^{II}Co^{III}_{0.33}Cr^{III}_{0.33}(CN)₄, Cd^{II}Fe^{III}_{0.33}Co^{III}_{0.33}(CN)₄, Cd^{II}Co^{II}_{0.33}Ir^{II}_{0.33}(CN)₄, Pd^{II}Cr^{II}_{0.33}Ir^{II}_{0.33}(CN)₄ and Cu^{II}Co^{III}_{0.66}(CN)₄.

(k) Other materials not explicitly belonging to classes (a) to (j) above that contained cyanide-bridged atoms. Included were cyanide-bridged materials in which the coordination spheres of some or all metal atoms included one or more non-cyanide bridges, such as water, alcohols, diols, thiols, oxalate, nitrate, nitrite, sulfate, phosphate, oxide, sulfide, thiocyanate, (non-bridging) cyanide, cyanate, nitrogen monoxide, carbon monoxide or dinitrogen. Such materials optionally consisted of regular nets, and optionally included interstitial ions or guest molecules. Examples included Ni^{II}(CN)₂.xH₂O, Fe₄[Re₆Se₈(CN)₆]₃.36H₂O, Cd^{II}Ni^{II}(CN)₄.xH₂O and Cd^{II}Pt^{II}(CN)₄ .xH₂O.

(l) Materials of the type described in (k) above that contained finite cyanide-bridged species. Such materials optionally contained cyanide-bridged polyhedra, polygons or finite chains. The cyanide-containing species optionally contained branches. Such materials also optionally contained components unrelated or unconnected to the cyanide-bridged moieties.

(m) Materials of the type described in (a) to (l) above where chemical composition varied within the one crystal/crystallite, as was achieved by variation of crystallisation conditions such as concentrations and temperatures during crystallisation. Examples included ZnₓCd₁₋ₓ(CN)₂.

(n) Materials of the type described in (a) to (l) above where structure type, guest inclusion or ion inclusion varied within the one crystal/crystallite, as was achieved by variation of crystallisation conditions such as concentrations and temperatures during crystallisation.

(o) Amorphous materials or glasses based on any of the systems defined in (a) to (n) above.

Preparations of these materials required a source of cyanide ions. Such sources included simple cyanide salts or their solutions, polycyanometallate salts or their solutions, cyanide precursors such as trimethylsilyl cyanide, organic nitrites, isocyanide salts or their solutions, organic isonitriles, hydrogen cyanide gas or its solutions, cyanohydrins or their solutions or any other cyanide-containing solid-, liquid-, gaseous- or solution-phase reagents.

Materials were then prepared by a number of methods, including:
(a) Slow diffusion of solutions containing the appropriate metal ions, any other coordinated ligands and a source of cyanide ions;
(b) Diffusion of reagents through thin films, gels or capillaries;
(c) Hydrothermal, solvothermal, and other high-temperature preparations;
(d) Solid-phase reactions, which optionally employed high temperatures and high pressures;
(e) Direct combination of reagents and isolation of products by techniques including precipitation and filtration, evaporation, crystallisation, sublimation and vapour deposition;
(f) Passage of hydrogen cyanide gas (or other gaseous cyanide-precursor) through solutions containing appropriate metal ions, ligands and guest molecules;
(g) Decomposition or reaction of one or more precursor compounds, in which volatile or reactive components of the precursor or precursors were removed or reacted;
(h) Vapour deposition of thin films by techniques including but not limited to chemical vapour deposition, physical vapour deposition, metal organic chemical vapour deposition and plasma assisted chemical vapour deposition;
(i) Vapour deposition of thin films of one or more precursor compounds followed by decomposition or reaction, in which volatile or reactive components of the precursor or precursors were removed or reacted.

Suitable materials had a number of features that made them suitable for physical application, including their facile synthesis, ready availability and unprecedented TTE behaviours.

Non-limiting examples illustrating cyanide-bridged materials having controllable expansion behaviour and a piezoelectric effect will now be described. The materials were characterised structurally. Their thermal expansion properties were also monitored by structural investigation.

From this, it was noted that a large and diverse family of materials exhibiting a range of useful thermal expansion properties and containing the same basic structural motif of cyanide-bridged atoms could be synthesised. In addition, materials with different degrees of interpenetration, topology, guest inclusion, charge, chemical composition and thermal expansion properties were proposed as suitable. Lattice effects were also noted to play a role in the thermal expansion properties of the compounds.

### EXAMPLE 1

First, four simple metal cyanide salts of the Zn(CN)₂ structural family, consisting of two interpenetrating diamond-type networks, with metal atoms acting as tetrahedral four-connectors, and cyanide ions as linear bridges, were synthesised as follows:
Zn(CN)₂ (A1);
ZnₓCd₁₋ₓ(CN)₂ (A2), where x˜0.80
ZnₓCd₁₋ₓ(CN)₂ (A3), where x˜0.64 and
Cd(CN)₂ (A4).

Further materials were synthesised by further variation of the metal units and had similar crystal morphologies indicating the framework structure was retained. In addition, the composition of the structure common to the compounds A1-A4 was varied systematically and it was noted that, with a potentially limitless number of solid solutions possible, the expansion properties of these materials were able to be fine-tuned.

Second, the lattice type, metal oxidation state and coordination preference of compounds A1-A4 were then varied. This enabled the discovery of unprecedented ZTE and a piezoelectric effect in chiral mixed-metal cyanides. The structure of these materials consisted of six interpenetrated beta-quartz-type nets, imparting a hexagonal, rather than cubic symmetry.

Then, two of those salts were characterised structurally, namely:
Zn^{II}[Ag^{I}(CN)₂]₂.0.575{AgCN} (B1) and
Zn^{II}[Au^{I}(CN)₂]₂ (B2).

Six quartz networks were observed to interpenetrate, each related by translation or rotation. As for quartz, each network was chiral, and each of the six interpenetrated networks in B1 and B2 had the same handedness. Advantageously, each was also observed to exhibit a piezoelectric effect.

Crystallographic details of B1 were: hexagonal, space group P6₂22, unit cell a=9.416(6) Å, c=18.13(1) Å, V=1392(3) Å³ (107 K); a=9.451(3) Å, c=18.217(5) Å, V=1409.2(7) Å³ (200 K).

Crystallographic details of B2 were: hexagonal, space group P6₂22, unit cell a=8.435(1) Å, c=20.785(4) Å, V=1280.7(6) Å³ (150 K); a=8.440(3) Å, c=20.723(5) Å, V=1278.2(8) Å³ (200 K).

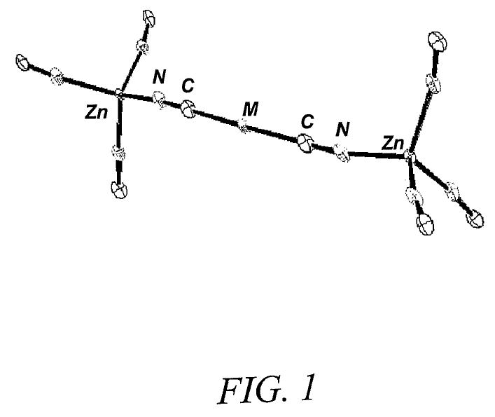

FIG. 1 is an ORTEP representation of the basic structural unit present in Zn^{II}[M^{I}(CN)₂]₂.x{guest}, (where M=Ag; Au and {guest} is as defined above), being part of the structures of B1 and B2. Each zinc atom (designated Zn) acts as a tetrahedral connector to four cyanide ions, being coordinated to the nitrogen atom of the four cyanide ions in a tetrahedral arrangement. Each gold or silver atom (designated M) acts as a slightly bent connector between two cyanide ions, the M atom being coordinated to the carbon atom of two cyanide ions in an approximately linear arrangement. Each cyanide ion (designated CN) acts as an approximately linear connector between a zinc atom and a gold or silver (M) atom.

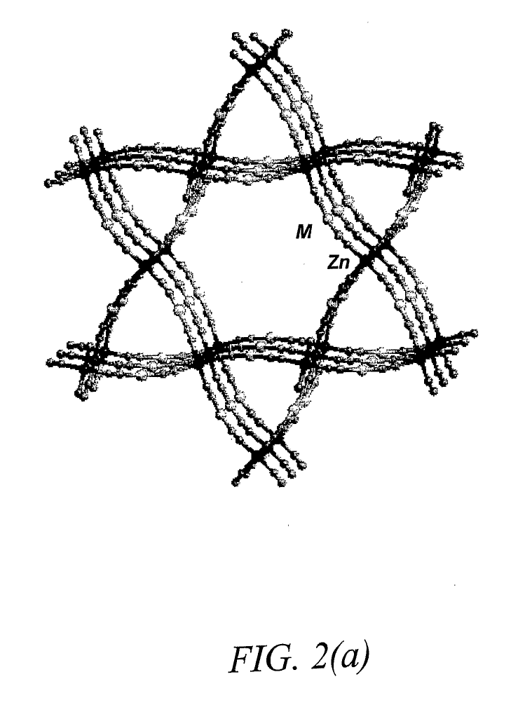

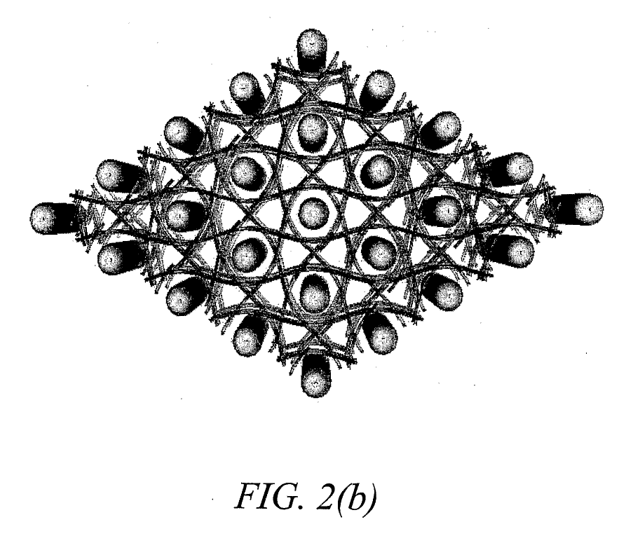

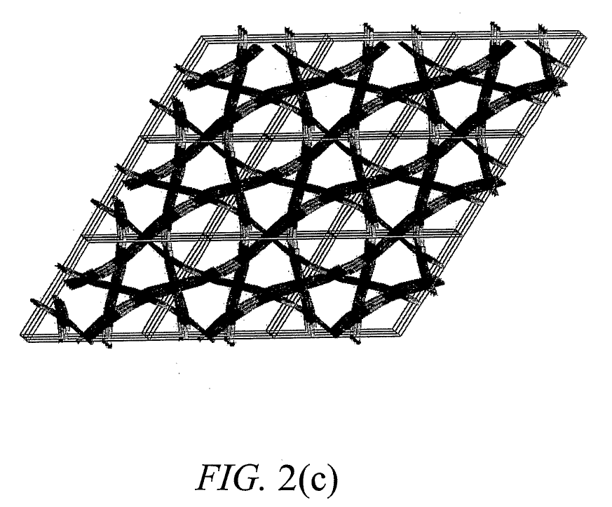

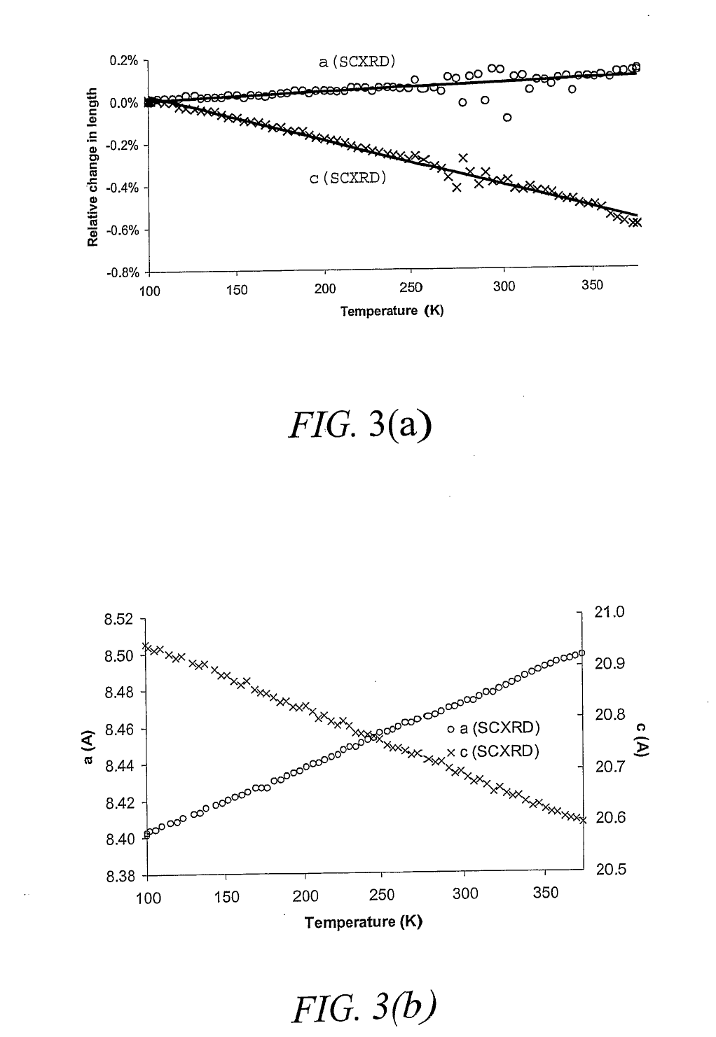

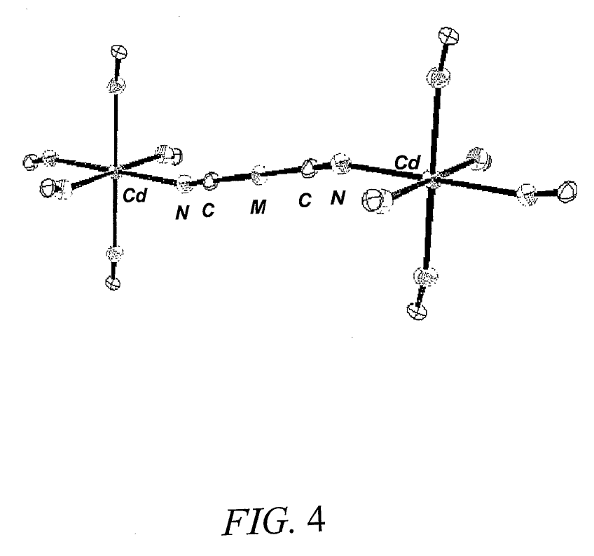

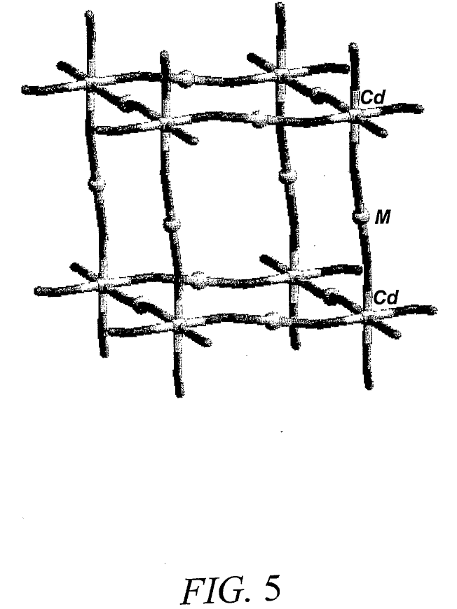

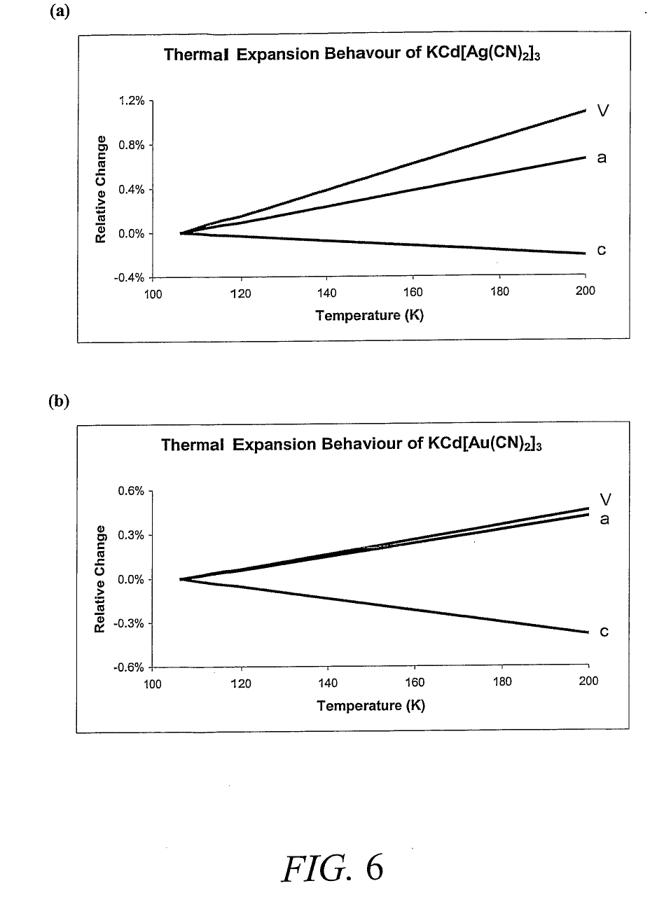

FIG. 2(a) illustrates one of the six interpenetrating beta-quartz-type networks that occurred in the structures of Zn^{II}[M^{I}(CN)₂]₂.x{guest}, (where M=Ag; Au and {guest} is as defined above), being part of the structures of B1 and B2. The M atoms are designated M and the zinc atoms are designated Zn. Each of the triangular channels in the representation is in fact a helix. Moreover, each helix has the same handedness, not only within each framework, but within the six frameworks that interpenetrate in the overall structure. Consequently, both materials grow as homochiral crystals and consequently rotate plane polarised light in only one direction.

FIGS. 2(b) and 2(c) illustrate the structures of B1 and B2, the structure of B1 containing 1-D chains of AgCN within the channels of the six interpenetrating networks, and the structure of B2 having empty channels.

FIGS. 3(a) and 3(b) show the relative changes in unit cell parameters that occurred when each Zn^{II}[M^{I}(CN)₂]₂.{guest} network was heated. The variation of the metal M had significant effect on the thermal expansion properties of the material. Also noted was the large negative change in the relative magnitude of the c-axis in Zn^{II}[Au^{I}(CN)₂]₂ and ZTE in other zxes.

Compositional variation of the metal sites in B1 and B2 provided a potentially limitless number of solid solutions with different thermal expansion properties. Further, the incorporation of different guest species provided a potentially limitless number of materials with different thermal expansion properties. The topological difference between A1-A4 and B1 and B2 illustrated further the structural variability within simple cyanide-bridged materials.

### EXAMPLE 2

Further variation of one of the metal components of B1 and B2 enabled the discovery of two new mixed-metal cyanides. These materials exhibited a different topology to that of B1 and B2, comprising three interpenetrating distorted cubic nets. Interstitial cations occupied vacancies between these nets. As observed for B2, these compounds exhibited an unprecedented ZTE and a piezoelectric effect.

Two salts were characterised structurally, namely:
KCd^{II}[Ag^{I}(CN)₂]₃ (C1) and
KCd^{II}[Au^{I}(CN)₂]₃ (C2).

Three distorted cubic nets interpenetrated, each related by translation or rotation. Vacancies between the nets were occupied by interstitial cations.

Crystallographic details of C1 were: hexagonal, space group P-3, unit cell a=6.855(3) Å, c=8.425(4) Å, V=342.9(3) Å³ (107 K); a=6.900 Å, c=8.407 Å, V=346.6 ÅA³ (200 K).

Crystallographic details of C2 were: hexagonal, space group P-3, unit cell a=6.777(3) Å, c=8.305(5) Å, V=330.3(3) Å³ (107 K); a=6.8052 Å, c=8.2732 Å, V=331.81 Å³ (200 K).

FIG. 4 shows an ORTEP representation of the basic structural unit in the KCd^{II}[M^{I}(CN)₃]₃ family (where M=Ag; Au), being part of the structure of compounds C1 and C2. Each cadmium atom (designated Cd) acts as an octahedral connector to six cyanide ions, being coordinated to the nitrogen atoms of six cyanide ions in an octahedral arrangement. Each silver or gold atom (designated M) acts as a linear connector between two cyanide ions, being coordinated by the carbon atoms of two cyanide ions. Each cyanide ion acts as a slightly-bent connector between a cadmium atom and a silver or gold atom. Potassium ions lie in interstitial cavities in which they are weakly coordinated by nitrogen atoms of surrounding cyanide ions (not shown in FIG. 4).

FIG. 5 illustrates one of the three interpenetrating distorted cubic networks that occur in the structure of the KCd^{II}[M^{I}(CN)₂]₃ family, being part of the structures of C1 and C2. The three nets interpenetrate, with interstitial cations occupying vacancies generated in the structure. The cadmium atoms (designated Cd) act as octahedral connectors to six M atoms through cyanide bridges. Each M atom (designated M) acts as a linear connector to two cadmium atoms through cyanide bridges.

FIGS. 6(a) and 6(b) show the thermal expansion behaviour of the family KCd^{II}[M^{I}(CN)₂]₃ (where M=Ag; Au), illustrating the relative changes in unit cell parameters that occur in each network when heated. Of note was NTE along the c-axis and ZTE along other axes. As noticed with the Zn^{II}M^{I}₂(CN)₄ family, NTE can be decreased and ZTE approached or reached upon replacement of gold atoms by silver atoms.

### EXAMPLE 3

### Compound Synthesis and Characterisation

### Synthesis

Single crystals of B1 were prepared by slow diffusion of solutions of silver(I) nitrate into stoichiometric (2:1) solutions of potassium tetracyanozincate(II). Alternatively, polycrystalline samples of B1 were prepared by diffusion of solutions of zinc(II) acetate into stoichiometric (1:2) solutions of potassium dicyanoargentate(I).

Large single crystals of B2 were prepared by slow diffusion of solutions of zinc(II) acetate into stoichiometric (1:2) solutions of potassium dicyanoaurate(I). The diffusion techniques included:
(a) Test tubes, where an aqueous solution of one reagent was layered above an aqueous solution of the other reagent. Often a buffer region of pure solvent was introduced between the two solutions;
(b) U-shaped tubes, where the reagents diffused toward one another through a curved region beneath the initial position of the solutions.

Large colourless hexagonal prisms were grown by each of these techniques over time periods ranging from days (test-tubes) to weeks (U-tubes). Each single crystal was observed to be homochiral and bulk samples consisted of equal quantities of enantiomorphic crystals.

### Structural Characterisation

Single crystals of B1 and B2 were mounted on a mohair fibre using a thin film of perfluoropolyether oil and transferred to a Bruker-AXS Smart 1000 CCD diffractometer equipped with Mo—Kα graphite monochromated radiation (lambda=0.71073 Å). The crystals were cooled rapidly to 107 K using an Oxford Instruments nitrogen cryostream. Further data collections were performed at 150 K (B2) and 200 K (B1).

Data collection, integration of frame data and conversion to intensities corrected for Lorentz, polarization and absorption effects were performed using the programs SMART, SAINT+ and SADABS. Structure solutions, refinement of the structures, structure analyses and production of crystallographic illustrations were carried out using the programs SHELXS-97, SHELXL-97, WebLab Viewer Pro and ORTEP.

### EXAMPLE 4

### Compound Synthesis and Characterisation

### Synthesis

Large single crystals of C1 and C2 were prepared by slow diffusion of solutions of cadmium(II) nitrate into stoichiometric (1:2) solutions of potassium dicyanoargentate(I) (C1) or potassium dicyanoaurate(I) (C2). Alternatively, single crystals of C1 were obtained by slow diffusion of solutions of silver(I) nitrate into stoichiometric (2:1) solutions of potassium tetracyanocadmate(II). Both compounds were also prepared as bulk samples without need for slow diffusion. Inspection indicated the high degree of crystallinity present in samples prepared in this way.

Diffusion techniques (described above) included the use of: (a) test tubes, where an aqueous solution of one reagent was layered above an aqueous solution of the other reagent; often, a buffer region of pure solvent was introduced between the two solutions; (b) U-shaped tubes, where the reagents diffused toward one another through a curved region beneath the initial position of the solutions.

Large colourless triangular and hexagonal platelets were grown by each of these techniques over time periods ranging from days (test-tubes) to weeks (U-tubes).

### Structural Characterisation

Single crystals of C1 and C2 were mounted on a mohair fibre using a thin film of perfluoropolyether oil and transferred to a Bruker-AXS Smart 1000 CCD diffractometer equipped with Mo—Kα graphite monochromated radiation (lambda=0.71073 Å). The crystals were cooled rapidly to 107 K using an Oxford Instruments nitrogen cryostream. Data were also collected at 200 K. Data collection, integration of frame data and conversion to intensities corrected for Lorentz, polarization and absorption effects were performed using the programs SMART, SAINT+ and SADABS.

Structure solutions, refinement of the structures, structure analyses and production of crystallographic illustrations were carried out using the programs SHELXS-97, SHELXL-97, WebLab Viewer Pro and ORTEP.

### Observations

The thermal expansion properties exhibited by the materials described above were observed to arise from the thermal population of transverse vibrational modes of cyanide ion bridges, thermal population of rigid unit modes (RUMs), lattice effects and from conventional causes of NTE in non-cyanide containing materials. In materials containing atoms bridged by cyanide ions, the most general cause of ZTE was thermal population of the transverse vibrational modes.

The exact number and effect of these modes was also observed to depend on the geometry and symmetry of the cyanide bridge. Where at least one of the modes was observed to contribute a negative component to the overall thermal expansion properties, by material modification and/or crystal cutting this could be counteracted, eliminated or avoided. Other aspects which contributed to the overall thermal expansion properties of the materials included their composition, topology and whether or not ions or guest molecules were included therein.

Judicious choice of the appropriate parameters allowed for preparation of materials with a range of desired thermal expansion behaviours.

### EXAMPLE 5

### Determining Material Characteristics

Various characteristics of the material KMn[Ag^{I}(CN)₂]₃ were investigated. These included: piezoelectric effect; measurement of oscillator performance Q; and measurement of the mechanical properties relating to Young's Modulus and ease of cutting and grinding (related to shear strength).

### Crystal Structure

The material KMn[Ag^{I}(CN)₂]₃ has a “3×cubic” phase, with the structure containing three interpenetrating cubic-type networks. The crystal system is 32, trigonal trapezoidal (which is the same as quartz).

### Piezoelectric Effect

The piezoelectric effect was measured along different directions (axes) of the KMn[Ag^{I}(CN)₂]₃ crystal in order to fully map the piezoelectric tensor of the crystal.

Initially the sample was prepared using X-ray orientation, and phase and symmetry were defined. Then, the crystal was cut and polished and electrodes fitted thereto. Material property measurements were then taken, including the piezoelectric coefficient, the electromechanical coupling coefficient and the dielectric coefficient, to ascertain the extent of the crystal's piezoelectric effect.

### Oscillator Performance Q

Oscillator performance Q was tested by measuring the resonance behaviour and the Q-value for a relevant oscillator mode of interest. The temperature dependence of the crystal at that mode of interest was then evaluated, noting that temperature stability is a critical factor in oscillator applications.

### Mechanical Properties

Mechanical properties of the crystal relevant to its performance in an oscillator were evaluated. These properties included crystal resonances properties (relating to Young's Modulus) and properties relating to the ease of cutting and grinding of the crystal (related to sheer strength).

Firstly, a full matrix of elastic properties were evaluated. The properties tested included Young's Modulus and bulk elastic properties, noting that the mechanical strength in the material KMn[Ag^{I}(CN)₂]₃ is anisotropic. Sheer strength properties were evaluated by qualitatively evaluating the crystal's ease of cutting and grinding.

### Results

The results of several of these tests are presented in the following Table 1:

TABLE 1
Characteristics of the Crystal KMn[Ag^{I}(CN)₂]₃

| Parameter | | | | | | | |
|---|---|---|---|---|---|---|---|
| C | C₁₁ = | C¹² = | C¹³ = | C¹⁴ = | C³³ = 10 * 10¹⁰ | C44 = | C⁶⁶ = |
| (N/m²) | 1.8659 * 10¹⁰ | 1.466 * 10¹⁰ | 0.3 * 10¹⁰ | −0.34736 * 10¹⁰ | | 1.48 * 10¹⁰ | 0.2 * 10¹⁰ |
| d | d¹¹ = 4.88 * 10⁻¹² | — | — | d¹⁴ = −1.26 * 10⁻¹² | — | — | — |
| (C/N) | | | | | | | |
| ∈ | ∈₁₁ = 42.524e⁻¹² = 4.8 | — | — | — | ∈₃₃ = 44.1e⁻¹² = 4.98 | — | — |
| | ∈₀ | | | | ∈₀ | | |
| k | k₁₁ = 0.1114 | — | — | k₁₄ = 0.069 | — | — | — |

In Table 1:
the C value represents a mechanical property of the crystal, namely, its elastic constant, which is related to Young's Modulus;
the d value represents the piezoelectric coefficient (charge/force or C/N) which indicates the crystal's piezoelectric effect;
the ε value represents the dielectric constant, which is also related to the piezoelectric effect [Cameron to advise if this is correct?];
the k value represents the coupling coefficient which is derived from a measurement of resonance frequency, and which is related to the oscillator performance Q of the crystal (also see Table 2 below).

In Table 1 the references 11, 12 etc through to 66, refer to the crystal axis along which the measurement is taken.

From these results, it can be seen that the material KMn[Ag^{I}(CN)₂]₃ has a coupling coefficient which is better than that of quartz (quartz has a K11=0.102). This demonstrates that KMn[Ag^{I}(CN)₂]₃ displays a better piezoelectric effect than the standard oscillator crystal quartz. In addition, the mechanical properties and oscillator performance of KMn[Ag^{I}(CN)₂]₃ are comparable to that of quartz, indicating that KMn[Ag^{I}(CN)₂]₃ can be used in place of quartz in a crystal oscillator. [Cameron to provide any further comments on what the results demonstrate].

Reference will now be made to Table 2. Table 2 presents the results of testing additional samples of KMn[Ag^{I}(CN)₂]₃ for resonance frequency:

TABLE 2
Resonance Frequency Measurement Data of
KMn [Ag^{I}(CN)₂]₃

| | Length | F_{R} | F_{A} |
|---|---|---|---|
| Sample | (mm) | (kHz) | (kHz) |
| #1 5/2004 | 2.60 [x] | 424.375 | 425.625 |
| #2 6/2004 | 3.50 [x] | 345.95 | 347.70 |

Note: Before polishing both ends.

| | | | |
|---|---|---|---|
| #1 5/2004 | 1.50 [x] | 420.175 | 422.9875 |
| #2 6/2004 | 2.90 [x] | 367.8825 | 370.2225 |

Note: After polishing x direction at both ends

The test results presented in Table 2 are for two different samples (#1 & #2) produced at two different times. The resonance frequency was measured for each sample before polishing both ends of the crystal and after polishing both ends in a given direction (as best determined by X-ray orientation and phase and symmetry definition).

An average of the resonance measurements for the samples with polished ends was then determined, and from this the coupling coefficient k11 was calculated to be 0.1261. This result was noted to be 26% better than that of quartz (in which k11=0.102).

In other words, these further tests demonstrated that the piezoelectric effect for KMn[Ag^{I}(CN)₂]₃ is substantially improved over that of quartz, and yet the temperature stability of KMn[Ag^{I}(CN)₂]₃ is also vastly improved to that of quartz (ie. to the extent that no temperature compensation is required in an oscillator manufactured using KMn[Ag^{I}(CN)₂]₃). [Cameron to add in any other further comments that are relevant in this section].

Any reference herein to a prior art document or use is not an admission that the document or use forms part of the common general knowledge of a skilled person in this field in Australia or elsewhere.

Whilst a number of specific material embodiments have been described, it should be appreciated that the material and resulting oscillators may take many other forms.

1. A crystal-controlled oscillator, the crystal being formed from a material that is suitable for use in the oscillator, characterised in that the thermal expansion characteristic of the material itself enables temperature dependence of the oscillator frequency to be controlled over an operating temperature range for the oscillator.

2. A timing device incorporating the crystal-controlled oscillator of claim 1.

3. An oscillator as claimed in claim 1 wherein the thermal expansion characteristic is anisotropic or isotropic.

4. An oscillator as claimed in claim 1 wherein the thermal expansion characteristic of the material is adapted by tuning the coefficient of thermal expansion of the material.

5. An oscillator as claimed in claim 4 wherein tuning is achieved by:
(1) modifying the composition of the crystal; and/or
(2) cutting the material along a direction that has zero or near zero thermal expansion (ZTE).

6. An oscillator as claimed in claim 1 wherein the operating temperature range in which controlled thermal expansion is maintained is from −200° C. to +150° C.

7. An oscillator as claimed in claim 6 wherein the operating temperature range in which controlled thermal expansion is maintained is from −55° C. to +125° C.

8. An oscillator as claimed in claim 1 wherein the material is formed from a crystalline material comprising a plurality of diatomic bridges, each diatomic bridge extending between two atoms in the material, and each diatomic bridge having at least one vibrational mode that causes the two atoms on either side of the bridge to be moved together to the same extent as competing vibrational mode(s) that cause the two atoms on either side of the bridge to be moved apart.

9. An oscillator as claimed in claim 8 wherein the material comprises a plurality of linear and/or non-linear diatomic bridges.

10. An oscillator as claimed in claim 9 wherein the material comprises linear cyanide —(CN)— bridges and/or non-linear cyanide bridges.

11. An oscillator as claimed in claim 1 wherein the material is: Zn^{II}[Ag^{I}(CN)₂]₂.0.575(AgCN}, Zn^{II}[Au^{I}(CN)₂]₂, KCd^{II}[Ag^{I}(CN)₂]₃, KMn[Ag^{I}(CN)₂]₃ or KCd^{II}[Au^{I}(CN)₂]₃.

12. An oscillator as claimed in claim 1 wherein the thermal expansion characteristic of the material is modified by one or more of:
selective doping of any metal sites present in the material;
modification of guest molecules in the material;
modification of counter-ions in the material; and/or
by altering the degree of interpenetration of material topology.

13. A crystal for an oscillator substantially as herein described with reference to the Examples and/or the accompanying drawings.

14. The use of a material in a crystal-controlled oscillator, characterised in that the thermal expansion characteristic of the material itself enables temperature dependence of the oscillator frequency to be controlled over an operating temperature range for the oscillator.

15. The use as claimed in claim 14 that is use of the oscillator in a timing device.

16. A method of fabricating a crystal for an oscillator from a piezoelectric material having a thermal expansion characteristic that enables temperature dependence of the oscillator frequency to be controlled over its operating temperature range, the method comprising the step of cutting the material in a manner that imparts to an oscillator formed therefrom a near zero, negligible or simple frequency dependence over its operating temperature range.

17. A method as claimed in claim 16 wherein the piezoelectric material is formed to have a zero or near zero thermal expansion characteristic along at least one axis therethrough.

18. A method as claimed in claim 16 wherein a crystal of the piezoelectric material is grown by slow diffusion at ambient temperature or by solvothermal synthesis at temperatures higher than ambient.

19. A method as claimed in claim 16 wherein, during formation of the piezoelectric material, the thermal expansion characteristic of the material is modified by selective doping of metal sites, modification of guest molecules, modification of counter-ions, and/or by altering the degree of interpenetration of material topology.

20. A method as claimed in claim 16 wherein, after formation of the piezoelectric material into a crystal, the thermal expansion properties of the crystal are optimised by cutting the crystal along a direction in which the material has a zero thermal expansion (ZTE) characteristic, or a characteristic closely approaching ZTE.

21. A method as claimed in claim 16 wherein the crystal forms part of an oscillator.

22. A method of fabricating a crystal substantially as herein described with reference to the Examples and/or the accompanying drawings.
